(19) United States
(12) Patent Application Publication
(10) Pub. No.: US 2020/0333651 A1
(43) Pub. Date: Oct. 22, 2020

(54) PROCESSING PLASTICS FILMS

(71) Applicant: Flexenable Limited, Cambridge (GB)

(72) Inventors: Agaiby Rouzet, Cambridge (GB); Jan Jongman, Cambridge (GB)

(21) Appl. No.: 16/851,352

(22) Filed: Apr. 17, 2020

(30) Foreign Application Priority Data
Apr. 18, 2019 (GB) 1905512.8

(51) Int. Cl. G02F 1/1333; H01L 27/12; B32B 43/00

(52) U.S. Cl. CPC G02F 1/133305; B32B 43/006; H01L 27/1266

(57) ABSTRACT

A technique comprising: processing a plastics film in situ on a first carrier; thereafter removing the processed plastics film from the first carrier; subjecting the processed plastics film to one or more quality checks; and following a determination that the processed plastics film meets one or more predetermined quality criteria, bonding the processed plastics film to a second carrier; further processing the processed plastics film in situ on the second carrier; and thereafter debonding the further processed plastics film from the second carrier using a process having a higher yield than that of the process of removing the processed plastics film from the first carrier.

### CLAIM OF PRIORITY

This application claims priority to Great Britain Patent Application No. 1905512.8, filed Apr. 18, 2019, the content of which is hereby incorporated by reference in its entirety.

### FIELD OF THE INVENTION

There is increasing demand for devices using flexible plastics films as support components in place of more rigid support components such as glass sheets. The processing of flexible plastics films to produce a device is typically performed in situ on a carrier to e.g. facilitate transport of the plastics film from one processing unit to another processing unit.

The inventors for the present application have conducted research into new ways of processing plastics films for the mass production of devices.

There is hereby provided a method comprising: processing a plastics film in situ on a first carrier; thereafter removing the processed plastics film from the first carrier; subjecting the processed plastics film to one or more quality checks; and following a determination that the processed plastics film meets one or more predetermined quality criteria, bonding the processed plastics film to a second carrier; further processing the processed plastics film in situ on the second carrier; and thereafter debonding the further processed plastics film from the second carrier using a process having a higher yield than that of the process of removing the processed plastics film from the first carrier.

According to one embodiment, the first and second carriers are separate elements.

According to one embodiment, processing the plastics film in situ on the first carrier involves higher temperature processing than the further processing of the processed plastics film on the second carrier.

According to one embodiment, processing the plastics film on the first carrier comprises forming conductor, semiconductor and insulator layers in situ on the plastics film to form a stack of layers defining at least electrical circuitry including one or more transistors having inorganic semiconductor channels; and wherein further processing the processed plastics film in situ on the second carrier comprises bonding the processed plastics film to another plastics film via a layer of liquid material.

According to one embodiment, the another plastics film is bonded to a third carrier, and further comprising debonding the another plastics film from the third carrier before or after debonding the plastics film from the second carrier.

According to one embodiment, the liquid material comprises a liquid crystal material, and wherein the stack of layers formed on the plastics film comprises an array of pixel electrodes, and electrical circuitry to independently address each pixel electrode via conductors outside the array of pixel electrodes.

According to one embodiment, the plastics film comprises a polyimide film.

According to one embodiment, the process of removing the plastics film from the first carrier comprises exposing an interface between the plastics film and the first carrier to relatively high intensity radiation through the first carrier; and the process of debonding the plastics film from the second carrier relies on a change of temperature of an adhesive between the plastics film and/or exposure of the adhesive to relatively low intensity radiation.

According to one embodiment, the process of removing the plastics film from the first carrier comprises laser lift-off delamination of the plastics film from the first carrier.

According to one embodiment, the method comprises forming the plastics film in situ on the first carrier.

According to one embodiment, processing the plastics film on the first carrier comprises forming conductor, semiconductor and insulator layers in situ on the plastics film to form a stack of layers defining at least electrical circuitry including one or more transistors having inorganic semiconductor channels; and wherein further processing the processed plastics film in situ on the second carrier comprises bonding the processed plastics film to another plastics film to create a microfluidic channel therebetween.

### BRIEF DESCRIPTION OF THE FIGURES

An example embodiment of the invention is described in detail below, by way of example only, with reference to the accompanying drawings, in which:

FIGS. 1-8 illustrate a process flow according to an example embodiment of the present invention;

FIGS. 9(A)-9(E) illustrate an example of a technique for use in the process flow of FIGS. 1-8; and

FIG. 10 illustrates an example of a process by which an adhesive layer is released from a carrier.

### DETAILED DESCRIPTION

An example embodiment is described below for the example of producing a liquid crystal (LC)cell for a liquid crystal display (LCD) device, but the technique is equally applicable to the production of other types of device (or components thereof) including, for example, other types of device that comprise liquid material between plastics film components, such as microfluidic devices.

The detailed description below makes mention of specific process details (specific materials etc.) that are not essential to achieving the technical effects described below. The mention of such specific process details is by way of example only, and other specific materials, processing conditions etc. may alternatively be used within the general teaching of the present application.

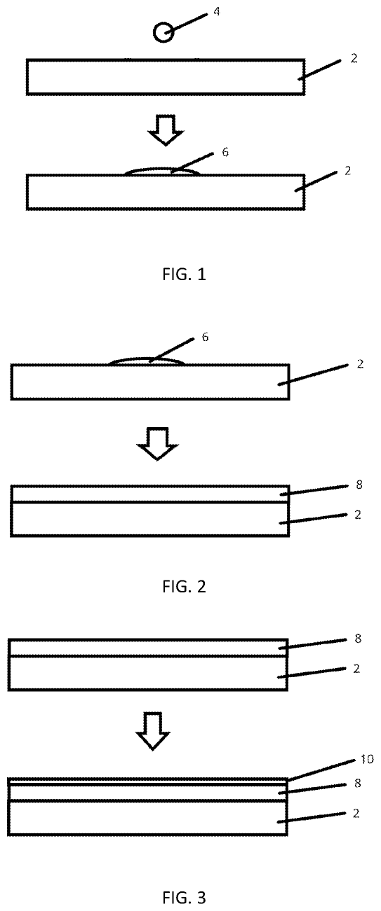

With reference to FIGS. 1 and 2, a substantially non-birefringent, transparent plastics film 8 is provided on a rigid carrier 2, such as a glass carrier. The attachment between the plastics film 8 and the carrier 2 is sufficiently strongly to retain the plastics film 8 in position on the carrier 2 during the relatively high temperature processing of the plastics film 8 in situ on the carrier 2. In this example, the plastics film 8 is provided on the carrier 2 by forming the plastics film in situ on the carrier 2, by e.g., a liquid processing technique such as spin-coating. A drop 4 of a solution/dispersion of the plastics film material (or a precursor thereto) is deposited on the carrier 2, and the carrier is thereafter spun at high speed to spread the content of the drop 4 over the surface of the carrier. After drying and one or more post-treatments such as e.g. annealing, a plastics film 8 of substantially uniform thickness is left secured to the carrier 2.

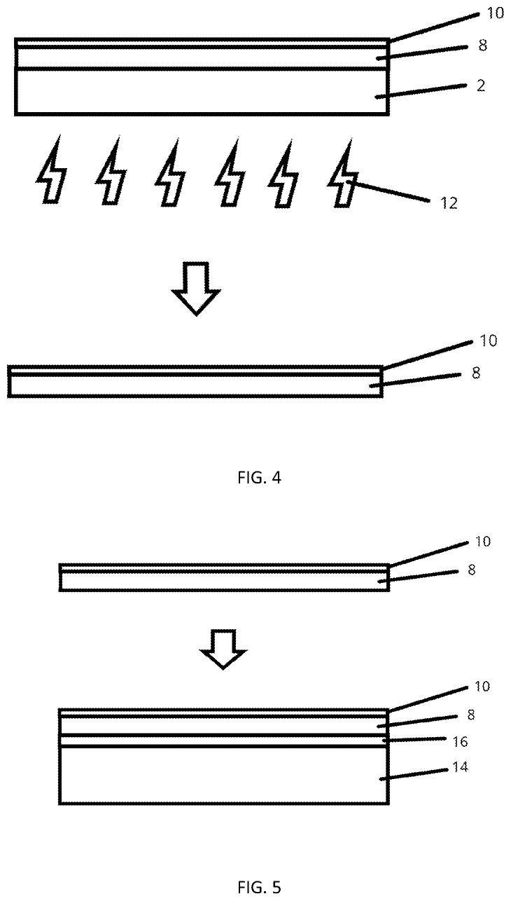

With reference to FIG. 3, layers (including patterned layers) of conductor, semiconductor and insulator materials are formed in situ on the plastics film 8 to form a stack of layers 10 defining at least an array of pixel electrodes and electrical circuitry including thin-film-transistors (TFTs) having inorganic semiconductor channels, for independently addressing each pixel electrode outside the array of pixel electrodes. In this example, the formation of this stack of layers 10 includes the deposition of at least one layer comprising an inorganic semiconductor (e.g., metal oxide semiconductor, low temperature polysilicon (LTPS), or amorphous silicon (a-Si)), by a liquid processing technique and a post-treatment comprising relatively high temperatures above about 250° C.

The stack of layers 10 may be designed for a LCD device in which both the pixel electrodes and the counter electrode are on the same side of the LC material (such as in-plane switching (IPS) devices and fringe-field switching (FFS) devices, or a LCD device in which the pixel electrodes and the counter electrode are on opposite sides of the LC material such as a twisted nematic (TN) type LCD device.

The stack of layers 10 may comprise an array of colour filters, each associated with a respective pixel electrode.

The top layer of the stack of layers is an LC alignment layer (e.g. rubbed polyimide (PI) layer), which together with an LC alignment layer on the opposite side of the LC material (discussed below), determines the orientation of the LC director (orientation of the molecules of the LC material) in the absence of an over-riding electric field generated by a potential difference between a pixel electrode and a counter electrode.

With reference to FIG. 4, the processed plastics film is thereafter removed from the carrier 2. In this example, this is done by a laser lift-off (LLO) delamination technique comprising exposing the interface between the plastics film 8 and the carrier to UV (308nm) laser 12 through the carrier 2. Polymer (e.g., polyimide) material at the interface with the carrier 2 is evaporated thereby releasing the processed plastics film from the carrier 2.

The released plastics film is then subjected to quality checking aimed at discarding any processed films that do not meet one or more quality criteria, because of e.g. defects caused by the LLO delamination process. With reference to FIG. 5, in the event of the processed plastics film passing the one or more quality checks, the released plastics film is thereafter bonded to another rigid carrier 14 (e.g., glass carrier) via an adhesive layer 16 (or an adhesive unit 16 comprising a plastics support film supporting adhesive films on both sides thereof (e.g., a UV release film on one side and a heat release film on the other side). A specific example of an adhesive unit is discussed further below.

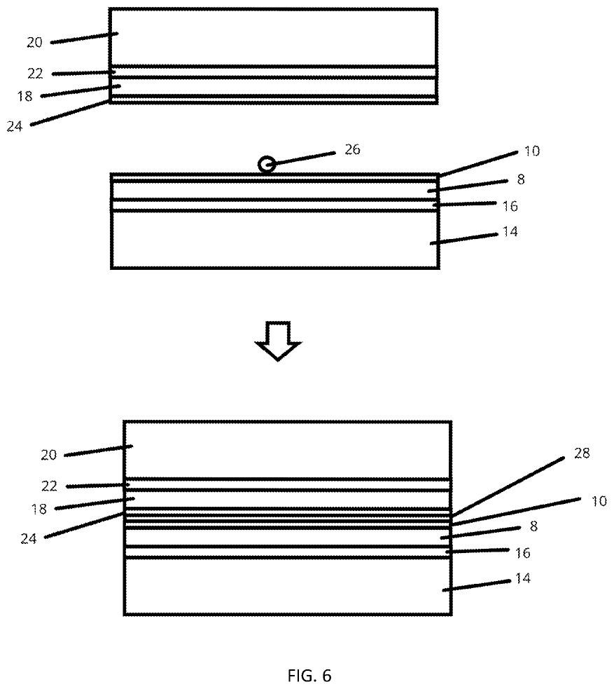

With reference to FIG. 6, a counter component is also prepared by e.g., bonding another flexible plastics film 18 to a rigid carrier 20 (e.g., glass carrier) via an adhesive layer 22 (or an adhesive unit 22 comprising a plastics support film supporting adhesive films on both sides thereof, and processing the plastics film 18 in situ on the carrier 20. This additional plastics film 18 may comprise the same material as that of plastic film 8 (or may comprise a different, substantially non-birefringent, transparent material having a similar coefficient of heat expansion as plastics film 8). Processing of the plastics film 18 in situ on the carrier 20 comprises forming a top LC alignment layer 24 (e.g., rubbed polyimide layer), and may also comprise e.g. forming a common conductor layer in situ on the plastics film 18 for the example of LCD devices having pixel electrodes and counter electrodes on opposite sides of the LC material.

In this example, a one-drop fill (ODF) technique is used to form a substantially uniform thickness of LC material between the two LC alignment layers on the two components. A drop of LC material 26 having at least sufficient volume to create a layer of the desired thickness over the active area of the display device is provided on one of the two LC alignment layers. Liquid, curable adhesive is also applied to one or both components outside the active display area, and the two components are forcibly pressed together under vacuum, by which the LC material 26 becomes spread over at least the active display area of the device, followed by curing of the curable adhesive while the two components pressed together. The necessary spacing between the two components (and thus the necessary thickness of LC material 28, which will depend on the type of LCD device) is ensured by e.g., spacing structures forming an integral part of one or both of the two components beneath the LC alignment layer(s), or separate spacing balls mixed in with the liquid, curable adhesive.

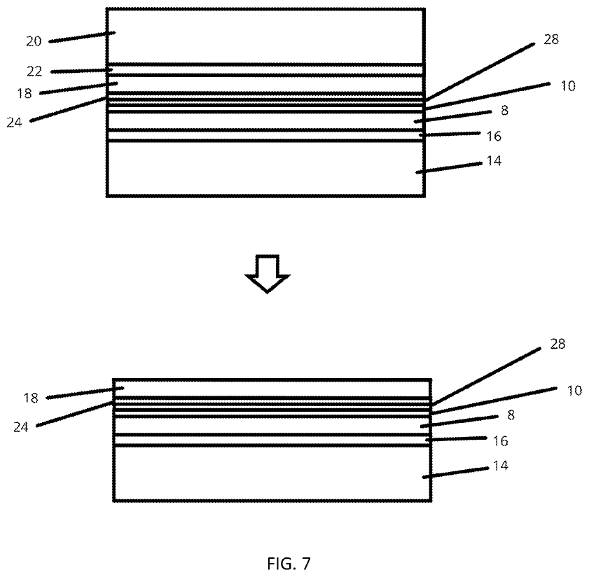

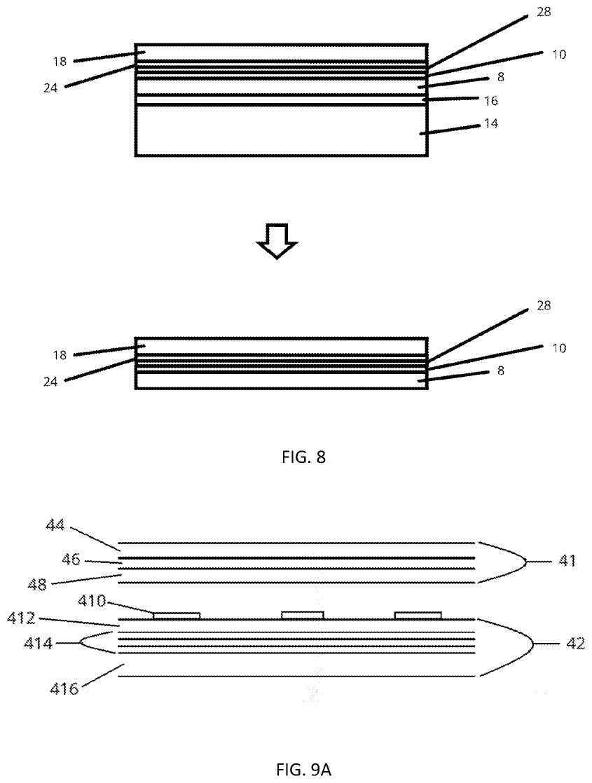

With reference to FIGS. 7 and 8, the carriers 2, 20 are thereafter released from the LC cell assembly in sequence, by a release technique exhibiting a higher yield than the LLO delamination technique used to release the processed plastics film from the carrier 2 used in forming the stack of layers 10 on plastic film 8.

The further processing of the plastics film 8 on the second carrier (e.g., deposition of LC material, and bonding to the counter component assemble the LC cell) does not involve the use of the high temperatures that are used in forming the stack of layers 10 on the plastics film 8 in situ on the first carrier. The processing of the additional plastics film 18 in situ on rigid carrier 20 also does not involve the use of the high temperatures that are used in forming the stack of layers 10 on the plastics film 8 in situ on the first carrier.

One example of a high yield technique for bonding together two plastics film components with support by temporary carriers is described in UK Patent Application No. 1608279.4 and International Patent Application No. PCT/EP2017/061319, from which content is reproduced below.

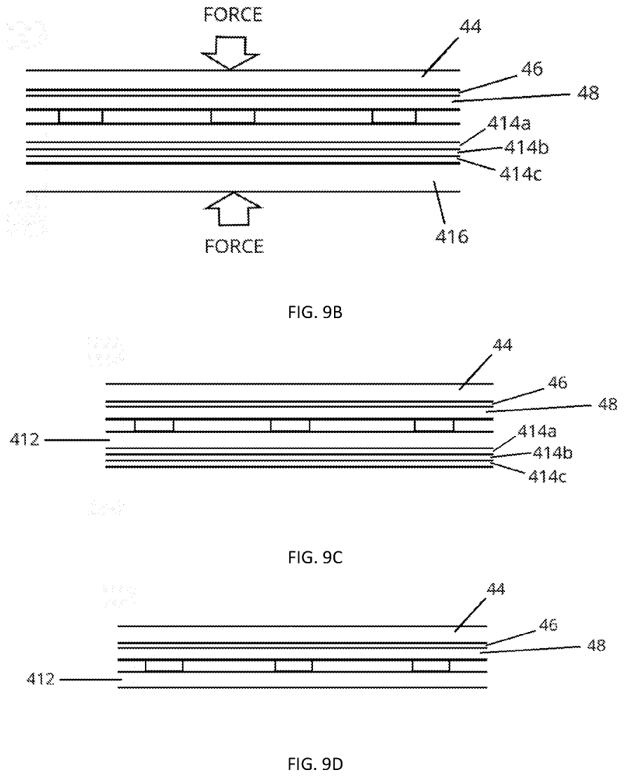

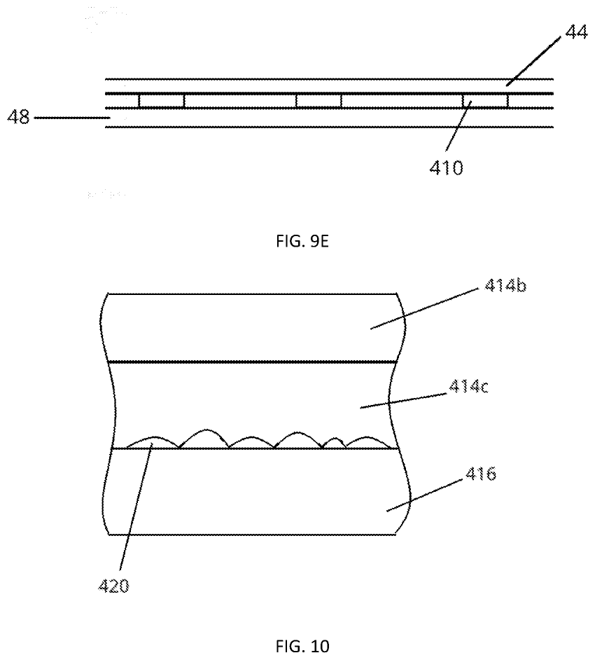

With reference to FIGS. 9A-9E, a first flexible component 48 is releasably secured to a rigid carrier 44 via an adhesive element 46, whose strength of adhesion to both the rigid carrier 44 and the flexible component is sufficiently high during processing of the assembly to resist excessive thermal expansion of the flexible component 48, but which either is (i) not too high to prevent peeling of the adhesive element 46 away from at least the assembly after processing or (ii) can be reduced after processing of the assembly to facilitate release of the adhesive element 46 from at least the assembly. For example, this adhesive element 46 may be a single layer of pressure-sensitive adhesive, or a single layer of adhesive whose adhesion strength to one or more of the first flexible component 48 and rigid carrier 44 can be reduced by increasing temperature (heat release), by reducing temperature (cold release) or by exposure to UV radiation (UV release). The adhesive element 46 may also comprise two layers of adhesive on opposite sides of a support film, which two layers may, for example, comprise any combination of a pressure-sensitive adhesive, a heat release adhesive, cold release adhesive and UV release adhesive.

A second flexible component 412 is releasably secured to another rigid carrier 416 via a dual-sided adhesive unit 14 comprising a support film 414b supporting a layer of heat-release adhesive 414c adjacent to the carrier 416 and a second layer of adhesive 414a adjacent to the flexible component 412. In this example, the second layer of adhesive 414a is one whose strength of adhesion to the second flexible component 412 is sufficiently high during processing of the assembly to resist excessive thermal expansion of the assembly, but which either (i) is not too high to prevent peeling of the adhesive element away from the assembly after processing or (ii) can be reduced after processing of the assembly to facilitate release of the adhesive element 414a from the assembly. The second layer of adhesive 414a may, for example, comprise (a) a pressure-sensitive adhesive, (b) a layer of heat-release adhesive having a higher release temperature than the first layer of adhesive 414c, (c) a layer of cold-release adhesive, or (d) a layer of UV-release adhesive.

In this example, at least one of the flexible components 48, 412 is provided with a heat-curable adhesive for securing the two flexible components together. The two flexible components 48, 412 are then aligned to one another (e.g., means of alignment marks included as part of the second flexible component and observable from above via the optically transparent carrier (e.g., glass) 44, optically transparent adhesive element 46, and optically transparent first flexible component 48) and mechanically compressed together (FIG. 9B) between the carriers 44, 416 via spacer structures 410. While under mechanical compression, the assembly (and carriers 44, 416) is uniformly heated in an oven (so as to establish a zero temperature gradient across the assembly) under conditions at which the adhesive between the two flexible components 48, 412 of the assembly becomes completely cured. Whether or not the adhesive between the two flexible components is completely cured can, for example, be determined by subjecting the assembly to a peel strength test and comparing the measured peel strength against a known or pre-determined maximum peel strength for the specific adhesive being used. Also, where the uncured form of the adhesive has a damaging effect on e.g., liquid crystal material to be contained within the assembly between the two flexible components, the existence of uncured adhesive (i.e., a failure to completely cure the adhesive) manifests itself as a degradation in the performance of the liquid crystal display device.

This heating may involve raising the temperature of the oven in a series of steps and maintaining the oven at each step temperature for a respective period of time. The heating required to cure the adhesive involves raising the temperature of the assembly to a temperature where crinkling of the plastic support films within the assembly tends to occur, but as discussed below, the pressure at which the assembly is mechanically compressed between the carriers is sufficiently high to substantially prevent any significant crinkling.

After sufficient heating has been performed to completely cure the adhesive between the two flexible components 48, 412, the temperature of the oven is reduced and the assembly and carriers inside the oven are allowed to cool, while continuing to mechanically compress the assembly between the two carriers to prevent crinkling of the plastic films during the cooling process. In this example, the adhesives used for the adhesive element 46 (between the first flexible component and the rigid carrier 4) and the adhesive used for adhesive layer 414a all retain their strength of adhesion to the assembly/carrier during the heating process to completely cure the adhesive between the two flexible components 48, 412. On the other hand, the heat-release adhesive for adhesive layer 414c is a material at which gas is generated during the process of heating the assembly to cure the adhesive between the two flexible components 48, 412. As described below with reference to FIG. 4, the generated gas forms pockets of gas 420 at the interface of the adhesive layer 414c with the rigid carrier 416, and the formation of these gas pockets 420 serves to partially reduce the strength of adhesion between the adhesive layer 414c and the carrier 416. The pressure at which the assembly is compressed between the two carriers 44, 416 is both (i) sufficiently low to retain the gas generated in the adhesive layer 414c as pockets of gas 420 at the interface between the adhesive layer 414c and the carrier 416 (i.e. to prevent gas generated within the adhesive layer 414c from being expelled laterally out from between the adhesive layer 414c and the carrier 416, but (ii) sufficiently high to prevent crinkling (distortion out of the plane) of the plastic support films within the assembly during the process of heating the assembly to cure the adhesive between the two flexible components.

The generation of gas within the adhesive layer 414c and the retention of generated gas at the interface of the adhesive layer 414c with the carrier 416 can be detected by: performing the heating in a vacuum and monitoring changes in pressure within the vacuum chamber; and/or remotely analysing, by e.g., spectroscopy, the interface between the adhesive layer 414c and the carrier 416.

After cooling the assembly to a temperature at which the plastic support films within the assembly no longer tend to crinkle (during which cooling, the gas pockets 420 continue to be retained at the interface of the adhesive layer 414c with the rigid carrier 416), mechanical compression of the assembly between the carriers is ended, and the combination of assembly and carriers 44, 416 is placed on a hotplate with the carrier 416 adjacent to adhesive layer 414c closest to the surface of the hotplate, such that a temperature gradient is established across the combination of adhesive element 414 and assembly. Without mechanically compressing the assembly between the carriers 44, 416, the hotplate is used to raise the temperature of the adhesive layer 414c to a temperature at which, in the absence of mechanical compression, the adhesive layer 414c thermally expands to an extent sufficient to further reduce the strength of adhesion between the adhesive layer 414c and the rigid carrier 416. This further heating of the adhesive layer 414c is done without increasing the temperature of the assembly to a temperature at which significant crinkling of the plastic support films within the assembly tends to occur. In one example, the temperature to which the adhesive layer 414c is raised may be above the maximum temperature that it reached during the heating process for curing the adhesive between the two flexible components 48, 412. However, release of the carrier 416 during this second heating stage can also be achieved at lower temperatures. The thermal expansion of the adhesive layer 414 during this second heating stage reduces the strength of adhesion between the adhesive material and the carrier 416 in the areas of contact around the gas pockets 420 at the interface between the carrier 416 and the adhesive layer 414c; and this further reduction in the strength of adhesion between the carrier and the adhesive layer 414c allows the carrier to be released from the assembly without the application of mechanical force or with the application of only minimal mechanical force (FIG. 9C).

The release of one rigid carrier 416 facilitates the peeling of the whole adhesive unit 414 from the assembly (FIG. 9D) and the subsequent peeling of the assembly away from adhesive unit 6 (FIG. 9D).

By way of example: an adhesive product acquired from Nitto Denko Corporation and identified by product name RAU-5HD1.SS was used for one of the adhesive units 414 in the technique described above; and an adhesive product acquired from Nitta Corporation and identified by product name CX2325CA3 was used for the other adhesive unit 46 in the technique described above. The adhesive product identified by product name RAU-5HD1.SS comprises a heat-release adhesive and a UV-release adhesive on opposite sides of a flexible support film, and the adhesive product identified by product name CX2325CA3 comprises a cold-release adhesive and a pressure sensitive adhesive supported on opposite sides of a flexible support film.

In the above-described example, the adhesive layer 414c adjacent to the carrier is the layer whose strength of adhesion to an adjacent element is partially reduced under mechanical compression during the heating process to cure the adhesive between the two carriers, and further reduced (without mechanical compression) after completion of the heating process to cure the adhesive between the two carriers. However, in an alternative example, this layer may be the adhesive layer 414a adjacent to the assembly in the adhesive unit 414 (whereby the adhesive unit 414 is first released from the assembly), or this layer may be a single layer of adhesive in contact with both the assembly and the carrier.

In the example described above, a heat-curable adhesive is used to secure the two flexible components together, but (a) an adhesive curable by exposure to e.g., UV radiation (UV-curable adhesive), (b) pressure-sensitive adhesive, or (c) an adhesive curable by laser, are other examples of adhesives that may be used to secure the two flexible components together. Even when the application of heat is not required to secure the two flexible components together, heating the assembly to a temperature at which crinkling of the plastic support films within the assembly tends to occur may be used for other purposes; and the above-described technique is equally useful in such situations.

As mentioned above, an example of a technique according to the present invention has been described in detail above with reference to specific process details, but the technique is more widely applicable within the general teaching of the present application. Additionally, and in accordance with the general teaching of the present invention, a technique according to the present invention may include additional process steps not described above, and/or omit some of the process steps described above.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

What is claimed is:

1. A method comprising:
processing a plastics film in situ on a first carrier; thereafter removing the processed plastics film from the first carrier;
subjecting the processed plastics film to one or more quality checks; and
following a determination that the processed plastics film meets one or more predetermined quality criteria, bonding the processed plastics film to a second carrier;
further processing the processed plastics film in situ on the second carrier; and
thereafter debonding the further processed plastics film from the second carrier using a process having a higher yield than that of the process of removing the processed plastics film from the first carrier.

2. The method according to claim 1, wherein the first and second carriers are separate elements.

3. The method according to claim 1, wherein processing the plastics film in situ on the first carrier involves higher temperature processing than the further processing of the processed plastics film on the second carrier.

4. The method according to claim 1, wherein processing the plastics film on the first carrier comprises forming conductor, semiconductor and insulator layers in situ on the plastics film to form a stack of layers defining at least electrical circuitry including one or more transistors having inorganic semiconductor channels; and wherein further processing the processed plastics film in situ on the second carrier comprises bonding the processed plastics film to another plastics film via a layer of liquid material.

5. The method according to claim 4, wherein the another plastics film is bonded to a third carrier, and further comprising debonding the another plastics film from the third carrier before or after debonding the plastics film from the second carrier.

6. The method according to claim 4, wherein the liquid material comprises a liquid crystal material, and wherein the stack of layers formed on the plastics film comprises an array of pixel electrodes, and electrical circuitry to independently address each pixel electrode via conductors outside the array of pixel electrodes.

7. The method according to claim 1, wherein the plastics film comprises a polyimide film.

8. The method according to claim 1, wherein the process of removing the plastics film from the first carrier comprises exposing an interface between the plastics film and the first carrier to relatively high intensity radiation through the first carrier; and the process of debonding the plastics film from the second carrier relies on a change of temperature of an adhesive between the plastics film and/or exposure of the adhesive to relatively low intensity radiation.

9. The method according to claim 8, wherein the process of removing the plastics film from the first carrier comprises laser lift-off delamination of the plastics film from the first carrier.

10. The method according to claim 1, comprising forming the plastics film in situ on the first carrier.

11. The method according to claim 1, wherein processing the plastics film on the first carrier comprises forming conductor, semiconductor and insulator layers in situ on the plastics film to form a stack of layers defining at least electrical circuitry including one or more transistors having inorganic semiconductor channels; and wherein further processing the processed plastics film in situ on the second carrier comprises bonding the processed plastics film to another plastics film to create a microfluidic channel therebetween.
